(19) United States
(12) Patent Application Publication
(10) Pub. No.: US 2023/0348759 A1
(43) Pub. Date: Nov. 2, 2023

(54) FILM, AND METHOD FOR MANUFACTURING SEMICONDUCTOR PACKAGE

(71) Applicant: AGC Inc., Tokyo (JP)

(72) Inventors: Satoshi TAKENAKA, Tokyo (JP); Seigo KOTERA, Tokyo (JP); Tetsuya HASEGAWA, Tokyo (JP)

(73) Assignee: AGC Inc., Tokyo (JP)

(21) Appl. No.: 18/348,406

(22) Filed: Jul. 7, 2023

Related U.S. Application Data
(63) Continuation of application No. PCT/JP2021/047062, filed on Dec. 20, 2021.

(30) Foreign Application Priority Data
Jan. 18, 2021 (JP) 2021-005780

(51) Int. Cl. C09J 7/40; H01L 21/56

(52) U.S. Cl. CPC C09J 7/401; H01L 21/566; C09J 2203/326

(57) ABSTRACT

A film including a substrate, a base layer, and an adhesive layer in this order, in which the base layer includes a reaction cured product of a (meth)acrylic polymer and a curing agent, and the base layer has an elongation rate of 90% or more as measured by a tensile test at 25° C. and a speed of 100 mm/min and determined by the following formula, Elongation rate (%)=(elongation (mm) at break)×100/(distance (mm) between grippers before applying tension).

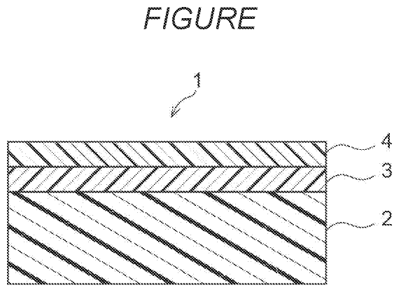

### CROSS-REFERENCE TO RELATED APPLICATIONS

This is a continuation of International Application No. PCT/JP2021/047062 filed on Dec. 20, 2021, and claims priority from Japanese Patent Application No. 2021-005780 filed on Jan. 18, 2021, the entire content of which is incorporated herein by reference.

### TECHNICAL FIELD

The present disclosure relates to a film and a method for manufacturing a semiconductor package.

### BACKGROUND ART

A semiconductor device is encapsulated in a form of a package and mounted on a substrate in order to block and protect the semiconductor device from outside air. A curable resin such as an epoxy resin is used for encapsulating the semiconductor device. Resin encapsulating is performed by placing a semiconductor device in a predetermined place in a mold, filling the mold with a curable resin, and curing the curable resin. A generally known encapsulating method includes a transfer molding method and a compression molding method. In encapsulating the semiconductor device, a mold release film is often placed on the inner surface of the mold in order to improve releasability of the package from the mold. For example, Patent Literatures 1 to 3 describe a film suitable for manufacturing a semiconductor package.

### CITATION LIST

### Patent Literature

Patent Literature 1: WO 2015/133630

Patent Literature 2: WO 2016/093178

Patent Literature 3: WO 2016/125796

### SUMMARY OF INVENTION

### Technical Problem

In a semiconductor package, a semiconductor device and an electronic component such as a source electrode and sealing glass may be exposed from an encapsulating resin for the purpose of improving heat dissipation or thinning the semiconductor package. A typical electronic component device having such an exposed portion is a sensor. A semiconductor package in which a part of an electronic component is exposed from an encapsulating resin is manufactured by filling a mold with a curable resin and curing the curable resin while a portion to be exposed is pressed against the mold.

When a mold release film is used in manufacture of the semiconductor package having such an exposed portion, encapsulating is performed in a state where the film and the exposed portion of the electronic component are in direct contact with each other. At this time, when the semiconductor package after encapsulating is peeled off from the film, a part of components of an adhesive layer of the film may remain attached to the electronic component and contaminate the electronic component. In order to deal with contamination of the electronic component due to migration of the film component, Patent Literature 3 proposes a film that includes a substrate having a specific storage elastic modulus and an adhesive layer containing a reaction cured product of an acrylic polymer having a specific functional group ratio and a polyfunctional isocyanate compound.

However, in recent years, as a semiconductor package shape has become more complicated and a height difference of a semiconductor package having an exposed portion has increased, use of a film that conforms to a complicated shape is increasing. At this time, it was found that a so-called adhesive residue, in which the component of the adhesive layer migrates to the encapsulated body as the film is stretched, is likely to occur, and the encapsulated body is likely to be contaminated.

The present disclosure relates to providing a film capable of preventing migration of a component of an adhesive layer to an encapsulated body even when the film is stretched, and a method for manufacturing a semiconductor package using the film.

### Solution to Problem

Means for solving the above problems include the following aspects.
<1>A film including a substrate, a base layer, and an adhesive layer in this order,
   in which the base layer includes a reaction cured product of a (meth)acrylic polymer and a curing agent, and
   the base layer has an elongation rate of 90% or more as measured by a tensile test at 25° C. and a speed of 100 mm/min and determined by the following formula,
   Elongation rate (%)=(elongation (mm) at break)×100/(distance (mm) between grippers before applying tension).
<2>A film including a substrate, a base layer, and an adhesive layer in this order,
   in which the base layer includes a reaction cured product of a (meth)acrylic polymer and a curing agent which is at least one selected from the group consisting of a metal chelate and an epoxy compound, and
   the (meth)acrylic polymer includes a carboxy group-containing (meth)acrylic polymer.
<3>The film according to <2>, in which the base layer has an elongation rate of 90% or more as measured by a tensile test at 25° C. and a speed of 100 mm/min and determined by the following formula,
   Elongation rate (%)=(elongation (mm) at break)×100/(distance (mm) between grippers before applying tension).
<4>The film according to any one of <1>to <3>, in which the base layer has an acid value of 1 mgKOH/g to 80 mgKOH/g.
<5>The film according to any one of <1>to <4>, in which the curing agent includes a metal chelate, and an amount of the metal chelate is 0.1 parts by mass to 10 parts by mass with respect to 100 parts by mass of the (meth)acrylic polymer.
<6>The film according to any one of <1>to <5>, in which the curing agent includes an epoxy compound, and an amount of the epoxy compound is 0.1 parts by mass to 10 parts by mass with respect to 100 parts by mass of the (meth)acrylic polymer.
<7>The film according to any one of <1>to <6>, in which the substrate includes a fluorine resin.
<8>The film according to <7>, in which the fluorine resin includes at least one selected from the group consisting of an ethylene-tetrafluoroethylene copolymer, a tetrafluoroethylene-hexafluoropropylene copolymer, a tetrafluoroethylene-perfluoro(alkyl vinyl ether) copolymer, and a tetrafluoroethylene-hexafluoropropylene-vinylidene fluoride copolymer.
<9>The film according to any one of <1>to <8>, in which the substrate is subjected to a corona treatment or a plasma treatment.
<10>The film according to any one of <1>to <9>, in which the adhesive layer includes a reaction cured product of a hydroxy group-containing (meth)acrylic polymer and a polyfunctional isocyanate compound.
<11>The film according to any one of <1>to <10>, further including an antistatic layer between the base layer and the adhesive layer.
<12>The film according to any one of <1>to <11>, being a mold release film used in a process of encapsulating a semiconductor device with a curable resin.
<13>A method for manufacturing a semiconductor package, the method including:
   placing the film according to any one of claims 1 to 12 in an inner surface of a mold;
   placing a substrate to which a semiconductor device is fixed in the mold in which the film is placed;
   encapsulating the semiconductor device in the mold with a curable resin to prepare an encapsulated body; and
   releasing the encapsulated body from the mold.

### ADVANTAGEOUS EFFECTS OF INVENTION

According to the present disclosure, a film capable of preventing migration of a component of an adhesive layer to an encapsulated body even when the film is stretched, and a method for manufacturing a semiconductor package using the film can be provided.

### BRIEF DESCRIPTION OF DRAWINGS

The figure is a schematic cross-sectional view of a film according to an aspect of the present disclosure.

### DESCRIPTION OF EMBODIMENTS

Hereinafter, embodiments of the present disclosure will be described in detail, but the embodiments of the present disclosure are not limited to the following embodiments.

In the present disclosure, the term “process” includes not only a process that is independent of other processes, but also a process that cannot be clearly distinguished from other processes, as long as the purpose of the process is achieved.

In the present disclosure, a numerical value range indicated by using “to” includes numerical values described before and after “to” as a minimum value and a maximum value, respectively.

In the present disclosure, each component may contain a plurality of kinds of corresponding substances. When a plurality of kinds of substances corresponding to the respective components are present in the composition, a content ratio or content of each component means a total content ratio or content of the plurality of kinds of substances present in the composition unless otherwise specified.

When embodiments are described in the present disclosure with reference to drawings, configurations of the embodiments are not limited to configurations shown in the drawings. The sizes of members in each drawing are conceptual, and a relative relationship between the sizes of the members is not limited thereto.

In the present disclosure, a “unit” of a polymer means a portion derived from a monomer that exists in the polymer and constitutes the polymer. A unit obtained by chemically converting a structure of a certain unit after polymer formation is also referred to as a unit. In some cases, a unit derived from an individual monomer is referred to by a name of the monomer followed by “unit”.

In the present disclosure, a film and a sheet are referred to as a “film” regardless of the thickness thereof.

In the present disclosure, acrylate and methacrylate are collectively referred to as “(meth)acrylate”, and acrylic and methacrylic are collectively referred to as “(meth)acrylic”.

In the present disclosure, a film according to a first embodiment and a film according to a second embodiment may be collectively referred to as a “film of the present disclosure”.

### «Film»

The film according to the first embodiment of the present disclosure includes a substrate, a base layer, and an adhesive layer in this order. The base layer contains a reaction cured product of a (meth)acrylic polymer and a curing agent. The base layer has an elongation rate of 90% or more as measured by a tensile test at 25° C. and a speed of 100 mm/min and determined by the following formula.

Elongation rate (%)=(elongation (mm) at break)×100/(distance (mm) between grippers before applying tension).

Hereinafter, the elongation rate measured by the above method is also simply referred to as an “elongation rate”.

The film according to the second embodiment of the present disclosure includes a substrate, a base layer, and an adhesive layer in this order. The base layer contains a reaction cured product of a (meth)acrylic polymer and a curing agent which is at least one selected from the group consisting of a metal chelate and an epoxy compound. The (meth)acrylic polymer includes a carboxy group-containing (meth)acrylic polymer.

It was found that the film of the present disclosure can prevent generation of adhesive residue particularly in device encapsulating of a semiconductor package having a complicated shape. The inventors presumed that when the film is stretched during the device encapsulating of the semiconductor package having a complicated shape, the adhesive layer of the film cannot follow the complicated shape and is broken, and as a result, the adhesive layer is peeled off from the substrate and is transferred to an encapsulating resin of the semiconductor package. Therefore, the present inventors have attempted to produce a film in which an adhesive layer can follow a complicated shape and is less likely to be peeled off from a substrate, and have developed the film of the present disclosure.

The film according to the first embodiment includes the base layer between the substrate and the adhesive layer. The base layer contains the reaction cured product of the (meth)acrylic polymer and the curing agent. The elongation rate of the base layer is 90% or more. It is considered that by providing the base layer having an elongation rate of 90% or more between the substrate and the adhesive layer, propagation of stress to the adhesive layer due to the elongation of the substrate is relaxed, and cracking of the adhesive layer can be prevented. Accordingly, it is considered that the adhesive layer is less likely to peel off from the substrate, and migration of a component of the adhesive layer can be prevented.

The film according to the second embodiment includes the base layer between the substrate and the adhesive layer. The base layer contains the reaction cured product of the (meth)acrylic polymer including a carboxy group-containing (meth)acrylic polymer and the curing agent which is at least one selected from the group consisting of a metal chelate and an epoxy compound. It is presumed that when a metal chelate is used as the curing agent for the (meth)acrylic polymer, a carboxy group in the (meth)acrylic polymer and the metal chelate form a loosely crosslinked structure through a coordinate bond, and thus a base layer having high stretchability can be obtained. It was found that even when an epoxy compound is used as the curing agent, a base layer having high stretchability can be obtained. It is considered that by providing such a base layer between the substrate and the adhesive layer, propagation of stress to the adhesive layer due to the elongation of the substrate is relaxed, and cracking of the adhesive layer can be prevented. Accordingly, it is considered that the adhesive layer is less likely to peel off from the substrate, and migration of a component of the adhesive layer can be prevented.

Hereinafter, a configuration example of the film will be described with reference to the drawings. The film of the present disclosure is not limited to the aspect of the drawings.

The figure is a schematic cross-sectional view showing one aspect of the film of the present disclosure. A film 1 includes a substrate 2, a base layer 3, and an adhesive layer 4 in this order. When the film is used to encapsulate a semiconductor device, the substrate 2 is placed in contact with a mold, and after resin encapsulating, the adhesive layer 4 is in contact with an encapsulated body (that is, a semiconductor package in which the semiconductor device is encapsulated). The film 1 may include other layers such as an antistatic layer.

Hereinafter, each layer of the film of the present disclosure will be described in detail.

### <Substrate>

A material of the substrate is not particularly limited, and from the viewpoint of releasability of the film, the substrate preferably contains a resin having releasability (hereinafter, also referred to as a “releasable resin”). The releasable resin means a resin in which a layer composed only of the resin has releasability. Examples of the releasable resin include a fluorine resin, a polymethylpentene, syndiotactic polystyrene, a polycycloolefin, a silicone rubber, a polyester elastomer, polybutylene terephthalate, and a cast nylon. From the viewpoint of the releasability from the mold, heat resistance at a mold temperature (for example, 180° C.) during encapsulating, strength to withstand a flow and pressure of the curable resin, elongation at a high temperature, and the like, a fluorine resin, a polymethylpentene, syndiotactic polystyrene, and a polycycloolefin are preferred, and from the viewpoint of excellent releasability, a fluorine resin is more preferred. The resin contained in the substrate may be used alone or in combination of two or more kinds thereof. The substrate is particularly preferably composed only of a fluorine resin.

The fluorine resin is preferably a fluoroolefin polymer from the viewpoint of excellent releasability and excellent heat resistance. The fluoroolefin polymer is a polymer having a unit based on a fluoroolefin. The fluoroolefin polymer may further have a unit other than the unit based on a fluoroolefin.

Examples of the fluoroolefin include tetrafluoroethylene (TFE), vinyl fluoride, vinylidene fluoride, trifluoroethylene, hexafluoropropylene, chlorotrifluoroethylene. The fluoroolefin may be used alone or in combination of two or more kinds thereof.

Examples of the fluoroolefin polymer include ETFE, a tetrafluoroethylene-hexafluoropropylene copolymer (FEP), a tetrafluoroethylene-perfluoro(alkyl vinyl ether) copolymer (PFA), and a tetrafluoroethylene-hexafluoropropylene-vinylidene fluoride copolymer (THV). The fluoroolefin polymer may be used alone or in combination of two or more kinds thereof.

The fluoroolefin polymer is preferably ETFE from the viewpoint of high elongation at a high temperature. The ETFE is a copolymer having a TFE unit and an ethylene unit (hereinafter also referred to as an “E unit”).

The ETFE is preferably a polymer having a TFE unit, an E unit, and a unit based on a third monomer other than TFE and ethylene. Depending on the type and content of the unit based on the third monomer, crystallinity of the ETFE can be easily adjusted, and accordingly, a storage elastic modulus or other tensile properties of the substrate can be easily adjusted. For example, when the ETFE has the unit based on the third monomer (particularly, a monomer having a fluorine atom), a tensile strength at a high temperature (particularly, at about 180° C.) tends to be improved.

Examples of the third monomer include a monomer having a fluorine atom and a monomer not having a fluorine atom.

Examples of the monomer having a fluorine atom include the following monomers (a1) to (a5).
Monomer (a1): fluoroolefins each having 2 or 3 carbon atoms
Monomer (a2): fluoroalkylethylenes represented by X(CF₂)ₙCY═CH₂ (in which X and Y each independently represent a hydrogen atom or a fluorine atom, and n is an integer of 2 to 8)
Monomer (a3): fluorovinylethers
Monomer (a4): functional group-containing fluorovinylethers
Monomer (a5): fluorine-containing monomer having an alicyclic structure

Examples of the monomer (a1) include fluoroethylenes (trifluoroethylene, vinylidene fluoride, vinyl fluoride, chlorotrifluoroethylene, etc.), fluoropropylenes (hexafluoropropylene (HFP), 2-hydropentafluoropropylene, etc.).

The monomer (a2) is preferably a monomer having n of 2 to 6, and more preferably a monomer having n of 2 to 4. A monomer whose X is a fluorine atom and Y is a hydrogen atom, that is, (perfluoroalkyl)ethylene is preferred.

Specific examples of the monomer (a2) include the following compounds.
CF₃CF₂CH═CH₂,
CF₃CF₂CF₂CF₂CH═CH₂ ((perfluorobutyl)ethylene (PFBE)),
CF₃CF₂CF₂CF₂CF═CH₂,
CF₂HCF₂CF₂CF═CH₂,
CF₂HCF₂CF₂CF₂CF═CH₂, etc.

Specific examples of the monomer (a3) include the following compounds. Among the following, a monomer that is a diene is a monomer capable of undergoing cyclopolymerization.
CF₂═CFOCF₃,
CF₂═CFOCF₂CF₃,
CF₂═CFO(CF₂)₂CF₃ (perfluoro(propyl vinyl ether) (PPVE)),
CF₂═CFOCF₂CF(CF₃)O(CF₂)₂CF₃,
CF₂═CFO(CF₂)₃O(CF₂)₂CF₃,
CF₂═CFO(CF₂CF(CF₃)O)₂(CF₂)₂CF₃,
CF₂═CFOCF₂CF(CF₃)O(CF₂)₂CF₃,
CF₂═CFOCF₂CF═CF₂,
CF₂═CFO(CF₂)₂CF═CF₂, etc.

Specific examples of the monomer (a4) include the following compounds.
CF₂═CFO(CF₂)₃CO₂CH₃,
CF₂═CFOCF₂CF(CF₃)O(CF₂)₃CO₂CH₃,
CF₂═CFOCF₂CF(CF₃)O(CF₂)₂SO₂F, etc.

Specific examples of the monomer (a5) include perfluoro(2,2-dimethyl-1,3-dioxole), 2,2,4-trifluoro-5-trifluoromethoxy-1,3-dioxole, and perfluoro(2-methylene-4-methyl-1,3-dioxolane).

Examples of the monomer not having a fluorine atom include the following monomers (b1) to (b4).
Monomer (b1): olefins,
Monomer (b2): vinyl esters,
Monomer (b3): vinyl ethers, and
Monomer (b4): an unsaturated acid anhydride.

Specific examples of the monomer (b1) include propylene and isobutene.

Specific examples of the monomer (b2) include vinyl acetate.

Specific examples of the monomer (b3) include ethyl vinyl ether, butyl vinyl ether, cyclohexyl vinyl ether, and hydroxybutyl vinyl ether.

Specific examples of the monomer (b4) include maleic anhydride, itaconic anhydride, citraconic anhydride, and 5-norbornene-2,3-dicarboxylic anhydride.

The third monomer may be used alone or in combination of two or more kinds thereof.

As the third monomer, the monomer (a2), HFP, PPVE, and vinyl acetate are preferred, HFP, PPVE, CF₃CF₂CH═CH₂, and PFBE are more preferred, and PFBE is even more preferred, from the viewpoint of easily adjusting the crystallinity and from the viewpoint of excellent tensile strength at a high temperature (particularly, at about 180° C.). That is, as the ETFE, a copolymer having a unit based on TFE, a unit based on E, and a unit based on PFBE is preferred.

In the ETFE, a molar ratio of the TFE unit to the E unit (TFE unit/E unit) is preferably 80/20 to 40/60, more preferably 70/30 to 45/55, and even more preferably 65/35 to 50/50. When the TFE unit/E unit is within the above range, the heat resistance and mechanical strength of the ETFE are excellent.

A proportion of the unit based on the third monomer in the ETFE is preferably 0.01 mol % to 20 mol %, more preferably 0.10 mol % to 15 mol %, and even more preferably 0.20 mol % to 10 mol %, with respect to a total (100 mol %) of all units constituting the ETFE. When the proportion of the unit based on the third monomer is within the above range, the heat resistance and mechanical strength of the ETFE are excellent.

When the unit based on the third monomer includes a PFBE unit, a proportion of the PFBE unit is preferably 0.5 mol % to 4.0 mol %, more preferably 0.7 mol % to 3.6 mol %, and even more preferably 1.0 mol % to 3.6 mol %, with respect to the total (100 mol %) of all units constituting the ETFE. When the proportion of the PFBE unit is within the above range, a tensile elastic modulus of the film at 180° C. can be adjusted within the above range. Further, the tensile strength at a high temperature, particularly at about 180° C., can be improved.

The substrate may be composed only of the releasable resin, or may further contain other components in addition to the releasable resin. Examples of the other components include a lubricant, an antioxidant, an antistatic agent, a plasticizer, and a mold release agent. The substrate preferably does not contain other components from the viewpoint of preventing staining of the mold.

A thickness of the substrate is preferably 25 μm to 250 μm, more preferably 25 μm to 100 μm, and even more preferably 25 μm to 75 μm. When the thickness of the substrate is equal to or less than an upper limit value of the above range, the film can be easily deformed and has excellent mold conformability. When the thickness of the substrate is equal to or more than a lower limit value of the above range, handling of the film, for example, roll-to-roll handling, is easy, and wrinkles are less likely to occur when the film is placed to cover a mold cavity while being pulled.

The thickness of the substrate can be measured in accordance with an ISO 4591:1992 (JIS K7130:1999) B1 method: a method for measuring a thickness of a sample taken from a plastic film or sheet by a mass method). Hereinafter, the same applies to the thickness of each layer of the film.

The surface of the substrate may have a surface roughness. An arithmetic average roughness Ra of the surface of the substrate is preferably 0.2 μm to 3.0 μm, and more preferably 0.2 μm to 2.5 μm. When the arithmetic average roughness Ra of the surface of the substrate is equal to or more than a lower limit value of the above range, the releasability from the mold is more excellent. Further, the surface of the substrate and the mold are less likely to cause blocking, and wrinkles due to blocking are less likely to occur. When the arithmetic average roughness Ra of the surface of the substrate is equal to or less than an upper limit value of the above range, pinholes are less likely to form in the film.

The arithmetic average roughness Ra is measured based on JIS B0601:2013 (ISO 4287:1997, Amd.1:2009). A reference length lr (a cutoff value λc) for a roughness curve is 0.8 5 mm.

A surface of the substrate adjacent to another layer may be subjected to any surface treatment. Examples of the surface treatment include a corona treatment, a plasma treatment, silane coupling agent coating, and adhesive coating. From the viewpoint of adhesion between the substrate and other layers, a corona treatment or a plasma treatment is preferred.

From the viewpoint of adhesion between the substrate and the adjacent layer, a wetting tension of the surface of the substrate on a base layer side is preferably 20 mN/m or more, more preferably 30 mN/m or more, and particularly preferably 35 mN/m or more. An upper limit of the wetting tension is not particularly limited, and the wetting tension may be 80 mN/m or less.

The substrate may be a single layer or may have a multilayer structure. Examples of the multilayer structure include a structure in which a plurality of layers each containing a releasable resin are laminated. In this case, the releasable resins contained in the plurality of layers may be the same as or different from each other. From the viewpoint of the mold conformability, the tensile elongation, a production cost, and the like, the substrate is preferably a single layer. From the viewpoint of film strength, the substrate preferably has a multilayer structure. The multilayer structure may be, for example, a structure in which a layer containing the above-described releasable resin (preferably a fluorine resin) is laminated on a resin film (which may be a film containing only a resin) containing a resin such as a polyester, a polybutylene terephthalate, a polystyrene (preferably syndiotactic), or a polycarbonate, or a structure in which a layer containing a first releasable resin, the resin film, and a layer containing a second releasable resin are laminated in this order. The layer containing the releasable resin and the resin film may be laminated via an adhesive. One surface or both surfaces of each layer containing the releasable resin may be subjected to the corona treatment or the plasma treatment. When the substrate has such a multilayer structure, the layer containing the releasable resin is preferably disposed on the base layer side. When the substrate has such a multilayer structure, it is preferred that the surface, on the base layer side, of the layer containing the releasable resin and disposed on the base layer side is subjected to the corona treatment or the plasma treatment.

### <Base Layer>

The base layer contains the reaction cured product of the (meth)acrylic polymer and the curing agent, and is provided between the substrate and the adhesive layer.

An acid value of the base layer is not particularly limited, and is preferably 1 mgKOH/g to 80 mgKOH/g, more preferably 1 mgKOH/g to 40 mgKOH/g, even more preferably 1 mgKOH/g to 30 mgKOH/g, and particularly preferably 5 mgKOH/g to 30 mgKOH/g. When the acid value is equal to or less than an upper limit value of the above range, the stretchability of the base layer is excellent. When the acid value is equal to or more than a lower limit value of the above range, adhesion of the base layer is excellent.

The acid value of the base layer is measured by a method defined in JIS K0070:1992. The acid value of the base layer can be calculated from the following formula.

Acid value (mgKOH/g) of base layer=((total mass of used carboxyl group-containing (meth)acrylic polymer)×acid value thereof)÷(total solid mass of used (meth)acrylic polymer, used metal chelate, and material added additionally)

When a plurality of kinds of carboxy group-containing (meth)acrylic polymers are used in the base layer, the “acid value” in the above formula is an arithmetic average value of the acid values of all of the plurality of kinds of carboxy group-containing (meth)acrylic polymers.

### ((Meth)acrylic Polymer)

The (meth)acrylic polymer is a polymer having a structural unit derived from a monomer having a (meth)acryloyl group or (meth)acrylic acid (hereinafter, the monomer having a (meth)acryloyl group or the (meth)acrylic acid is also referred to as a “(meth)acrylic monomer”). A proportion of the structural unit derived from the (meth)acrylic monomer to a total (meth)acrylic polymer is not particularly limited, and is preferably 50 mass % or more, more preferably 60 mass % or more, even more preferably 70 mass % or more, and particularly preferably 80 mass % or more.

The (meth)acrylic monomer which is a polymerization component of the (meth)acrylic polymer may be one kind or two or more kinds. Examples of the (meth)acrylic monomer include a (meth)acrylate not containing a hydroxy group and a carboxy group, a hydroxy group-containing (meth)acrylate, a carboxy group-containing (meth)acrylate, and (meth)acrylic acid. The (meth)acrylic polymer may be a polymer obtained by polymerizing any combination of these (meth)acrylic monomers.

Examples of the (meth)acrylate not containing a hydroxy group and a carboxy group include an alkyl (meth)acrylate, cyclohexyl (meth)acrylate, phenyl (meth)acrylate, toluyl (meth)acrylate, benzyl (meth)acrylate, 2-methoxyethyl (meth)acrylate, 3-methoxybutyl (meth)acrylate, glycidyl (meth)acrylate, 2-aminoethyl (meth)acrylate, 3-(methacryloyloxypropyl)trimethoxysilane, trifluoromethylmethyl (meth)acrylate, 2-trifluoromethylethyl (meth)acrylate, 2-perfluoroethylethyl (meth)acrylate, 2-perfluoroethyl-2-perfluorobutylethyl (meth)acrylate, 2-perfluoroethyl (meth)acrylate, perfluoromethyl (meth)acrylate, diperfluoromethylmethyl (meth)acrylate, 2-perfluoromethyl-2-perfluoroethylmethyl (meth)acrylate, 2-perfluorohexylethyl (meth)acrylate, 2-perfluorodecylethyl (meth)acrylate, and 2-perfluorohexadecylethyl (meth)acrylate.

The alkyl (meth)acrylate is preferably a compound whose alkyl group has 1 to 12 carbon atoms. Examples thereof include methyl (meth)acrylate, ethyl (meth)acrylate, butyl (meth)acrylate, 2-ethylhexyl (meth)acrylate, n-propyl (meth)acrylate, isopropyl (meth)acrylate, isobutyl (meth)acrylate, t-butyl (meth)acrylate, n-pentyl (meth)acrylate, n-hexyl (meth)acrylate, n-heptyl (meth)acrylate, n-octyl (meth)acrylate, nonyl (meth)acrylate, decyl (meth)acrylate, and dodecyl (meth)acrylate.

Examples of the hydroxy group-containing (meth)acrylate include 2-hydroxyethyl (meth)acrylate, 2-hydroxypropyl (meth)acrylate, 4-hydroxybutyl (meth)acrylate, 1,4-cyclohexanedimethanol monoacrylate, and 2-acryloyloxyethyl-2-hydroxyethyl-phthalic acid.

Examples of the carboxy group-containing (meth)acrylate include ω-carboxy-polycaprolactone mono(meth)acrylate.

Examples of the (meth)acrylic acid include acrylic acid and methacrylic acid.

In one aspect, the (meth)acrylic polymer preferably includes a carboxy-containing (meth)acrylic polymer. Examples of the carboxy group-containing (meth)acrylic polymer include a (meth)acrylic polymer containing a carboxy group-containing monomer as a constituent component, for example, a (meth)acrylic polymer containing a carboxy group-containing (meth)acrylic monomer as a polymerization component. Examples of the carboxy group-containing (meth)acrylic monomer include the carboxy group-containing (meth)acrylate and (meth)acrylic acid. The carboxy group-containing (meth)acrylic polymer may contain only a carboxy group-containing (meth)acrylic monomer as a constituent component, or may be a copolymer of a carboxy group-containing (meth)acrylic monomer and other monomers.

A mass average molecular weight (Mw) of the (meth)acrylic polymer is preferably 10,000 to 1,000,000, more preferably 50,000 to 800,000, and even more preferably 100,000 to 600,000. When the Mw is equal to or more than a lower limit value of the above range, strength of the base layer is excellent. When the Mw is equal to or less than an upper limit value of the above range, the stretchability of the base layer is excellent.

An Mw of the carboxy group-containing (meth)acrylic polymer is preferably 10,000 to 1,000,000, more preferably 50,000 to 800,000, and even more preferably 100,000 to 600,000. When the Mw is equal to or more than a lower limit value of the above range, strength of the base layer is excellent. When the Mw is equal to or less than an upper limit value of the above range, the stretchability of the base layer is excellent.

The Mw of the (meth)acrylic polymer is a value in terms of polystyrene, which is obtained by measurement by gel permeation chromatography using a calibration curve prepared using a standard polystyrene sample having a known molecular weight.

An acid value of the (meth)acrylic polymer is not particularly limited, and is preferably 1 mgKOH/g to 80 mgKOH/g, more preferably 1 mgKOH/g to 40 mgKOH/g, even more preferably 1 mgKOH/g to 30 mgKOH/g, and particularly preferably 5 mgKOH/g to 30 mgKOH/g. When the acid value is equal to or less than an upper limit value of the above range, the stretchability of the base layer is excellent. When the acid value is equal to or more than a lower limit value of the above range, adhesion of the base layer is excellent. When a plurality of kinds of (meth)acrylic polymers are used in the base layer, the range is a preferred range of the acid value of whole of the plurality of kinds of (meth)acrylic polymers.

An acid value of the carboxy group-containing (meth)acrylic polymer is not particularly limited, and is preferably 1 mgKOH/g to 80 mgKOH/g, more preferably 1 mgKOH/g to 40 mgKOH/g, even more preferably 1 mgKOH/g to 30 mgKOH/g, and particularly preferably 5 mgKOH/g to 30 mgKOH/g. When the acid value is equal to or less than an upper limit value of the above range, the stretchability of the base layer is excellent. When the acid value is equal to or more than a lower limit value of the above range, adhesion of the base layer is excellent.

The acid value of the (meth)acrylic polymer is measured by a method defined in JIS K0070:1992. The acid value of the (meth)acrylic polymer is an index of easiness of formation of crosslinks when reacting with a curing agent.

### (Curing Agent)

The curing agent is not particularly limited as long as it reacts with the (meth)acrylic polymer to cause curing. Examples of the curing agent include a polyfunctional isocyanate compound, a metal chelate, and an epoxy compound.

Examples of the polyfunctional isocyanate compound include a polyfunctional isocyanate compound described below as a component of the adhesive layer.

In one aspect, the curing agent may be at least one selected from the group consisting of a metal chelate and an epoxy compound. In one aspect, the base layer contains a reaction cured product of a (meth)acrylic polymer and a curing agent including at least one selected from the group consisting of a metal chelate and an epoxy compound, and the (meth)acrylic polymer includes a carboxy group-containing (meth)acrylic polymer.

### Metal Chelate

Examples of the metal chelate include a compound obtained by coordinately bonding a polyvalent metal atom and an organic compound. The metal chelate may be used alone or in combination of two or more kinds thereof.

Examples of the polyvalent metal atom include Al, Zr, Co, Cu, Fe, Ni, V, Zn, In, Ca, Mg, Mn, Y, Ce, Sr, Ba, Mo, La, Sn, and Ti. From the viewpoint of a low cost and easy 10 availability, at least one selected from the group consisting of Al, Zr, and Ti is preferred, and Al is more preferred.

Examples of the organic compound that is coordinately bonded to a polyvalent metal atom include an organic compound having an oxygen atom. Examples of the organic compound having an oxygen atom include an alkyl ester, an alcohol compound, a carboxylic acid compound, an ether compound, and a ketone compound.

From the viewpoint of relatively stable and easy handling, the metal chelate is preferably an aluminum chelate. Examples of the aluminum chelate include aluminum trisacetylacetonate.

When the curing agent contains the metal chelate, an amount of the metal chelate is preferably 0.1 parts by mass to 10 parts by mass, more preferably 0.5 parts by mass to 10 parts by mass, even more preferably 1.0 part by mass to 10 parts by mass, and particularly preferably 2.5 parts by mass to 10 parts by mass, with respect to 100 parts by mass of the (meth)acrylic polymer. When the amount of the metal chelate is equal to or less than an upper limit value of the above range, peeling of the adhesive layer due to an increase in unreacted metal chelate can be prevented. When the amount of the metal chelate is equal to or more than a lower limit value of the above range, peeling of the adhesive layer due to an increase in unreacted (meth)acrylic polymer can be prevented.

When the curing agent includes a metal chelate and is used in combination with the carboxy group-containing (meth)acrylic polymer, an amount of the metal chelate is preferably 0.1 parts by mass to 10 parts by mass, more preferably 0.5 parts by mass to 10 parts by mass, even more preferably 1.0 part by mass to 10 parts by mass, and particularly preferably 2.5 parts by mass to 10 parts by mass, with respect to 100 parts by mass of the carboxy group-containing (meth)acrylic polymer. When the amount of the metal chelate is equal to or less than an upper limit value of the above range, peeling of the adhesive layer due to an increase in unreacted metal chelate can be prevented. When the amount of the metal chelate is equal to or more than a lower limit value of the above range, peeling of the adhesive layer due to an increase in unreacted carboxy group-containing (meth)acrylic polymer can be prevented.

### Epoxy Compound

Examples of the epoxy compound include a compound having two or more epoxy groups in one molecule. The number of epoxy groups of the epoxy compound is preferably 2 or more, and more preferably 2 to 6.

Examples of the epoxy compound include N,N,N′,N′-tetraglycidyl-m-xylylenediamine, 1,3-bis(N,N-diglycidylaminomethyl)cyclohexane, resorcinol diglycidyl ether, and glycerol polyglycidyl ether. The epoxy compound may be used alone or in combination of two or more kinds thereof.

As the epoxy compound, a commercially available product may be used. Examples of the commercially available product include TETRAD-X (trade name) and TETRAD-C (trade name) manufactured by Mitsubishi Gas Chemical Company, Inc., and Denacol (registered trademark) EX-201 (trade name) and Denacol (registered trademark) EX-313 (trade name) manufactured by Nagase ChemteX Corporation.

An epoxy equivalent of the epoxy compound is preferably 300 g/eq or less, more preferably 200 g/eq or less, even more preferably 150 g/eq or less, and particularly preferably 120 g/eq or less from the viewpoint of obtaining high stretchability without excessively increasing a crosslinking density. From the viewpoint of increasing the strength of the base layer, the epoxy equivalent of the epoxy compound is preferably 30 g/eq or more, more preferably 50 g/eq or more, and even more preferably 90 g/eq or more. From such a viewpoint, the epoxy equivalent of the epoxy compound is preferably 30 g/eq to 300 g/eq, more preferably 50 g/eq to 200 g/eq, and even more preferably 90 g/eq to 120 g/eq.

When the curing agent includes an epoxy compound, an amount of the epoxy compound is preferably 0.1 parts by mass to 10 parts by mass, more preferably 0.5 parts by mass to 10 parts by mass, even more preferably 1.0 part by mass to 10 parts by mass, and particularly preferably 2.5 parts by mass to 10 parts by mass, with respect to 100 parts by mass of the (meth)acrylic polymer. When the amount of the epoxy compound is equal to or less than an upper limit value of the above range, peeling of the adhesive layer due to an increase in unreacted epoxy compound can be prevented. When the amount of the epoxy compound is equal to or more than a lower limit value of the above range, peeling of the adhesive layer due to an increase in unreacted (meth)acrylic polymer can be prevented.

When the curing agent includes the epoxy compound and is used in combination with the carboxy group-containing (meth)acrylic polymer, an amount of the epoxy compound is preferably 0.1 parts by mass to 10 parts by mass, more preferably 0.5 parts by mass to 10 parts by mass, even more preferably 1.0 part by mass to 10 parts by mass, and particularly preferably 2.5 parts by mass to 10 parts by mass, with respect to 100 parts by mass of the (meth)acrylic polymer. When the amount of the epoxy compound is equal to or less than an upper limit value of the above range, peeling of the adhesive layer due to an increase in unreacted epoxy compound can be prevented. When the amount of the epoxy compound is equal to or more than a lower limit value of the above range, peeling of the adhesive layer due to an increase in unreacted carboxy group-containing (meth)acrylic polymer can be prevented.

### [Thickness of Base Layer]

A thickness of the base layer is preferably 0.1 μm to 3.0 μm, more preferably 0.2 gm to 2.5 μm, and even more preferably 0.3 μm to 2.0 μm. When the thickness of the base layer is equal to or more than a lower limit value of the above range, stress relaxation against the elongation of the substrate is excellent. When the thickness of the base layer is equal to or less than an upper limit value of the above range, coating stability of the adhesive layer is excellent.

### [Elongation Rate of Base Layer]

An elongation rate of the base layer is preferably 90% or more, more preferably 100% or more, even more preferably 150% or more, particularly preferably 200% or more, and extremely preferably 300% or more. An upper limit of the elongation rate is not particularly limited, and the elongation rate may be 600% or less or 500% or less. The elongation rate of the base layer is measured under the following conditions.

A tensile test is performed under conditions of 25° C. and a speed of 100 mm/min, and the elongation rate is determined by the following formula.

Elongation rate (%)=(elongation (mm) at break)×100/(distance (mm) between grippers before applying tension).

Specifically, the elongation rate is measured by a method described in Examples.

A method of adjusting the elongation rate of the base layer is not particularly limited, and the elongation rate can be adjusted by adjusting the type, formulation, and the like of the component of the base layer. For example, the elongation rate can be adjusted to 90% or more by blending the component of the base layer so as to reduce the crosslinking density, selecting the component of the base layer so as to make the crosslinked structure loose, or the like.

### <Adhesive Layer>

The adhesive layer is a layer having adhesiveness to other members. A material of the adhesive layer is not particularly limited. In one aspect, the adhesive layer may contain a reaction cured product of a hydroxy group-containing (meth)acrylic polymer and a polyfunctional isocyanate compound. In this case, the hydroxy group-containing (meth)acrylic polymer reacts with the polyfunctional isocyanate compound to crosslink and form a reaction cured product. The adhesive layer may be a reaction cured product of a hydroxy group-containing (meth)acrylic polymer, a polyfunctional isocyanate compound, and other components.

### (Hydroxy Group-containing (Meth)acrylic Polymer)

A hydroxy group in the hydroxy group-containing (meth)acrylic polymer is a crosslinkable functional group that reacts with an isocyanate group in the polyfunctional isocyanate compound.

A hydroxyl value of the hydroxy group-containing (meth)acrylic polymer is preferably 1 mgKOH/g to 100 mgKOH/g, and more preferably 29 mgKOH/g to 100 mgKOH/g. The hydroxyl value is measured by a method defined in JIS K0070:1992.

The hydroxy group-containing (meth)acrylic polymer may or may not have a carboxy group. Similar to the hydroxy group, the carboxy group is a crosslinkable functional group that reacts with the isocyanate group in the polyfunctional isocyanate compound. An acid value of the hydroxy group-containing (meth)acrylic polymer is preferably 0 mgKOH/g to 100 mgKOH/g, and more preferably 0 mgKOH/g to 30 mgKOH/g. The acid value is measured by the method defined in JIS K0070:1992 as in the case of the hydroxyl value.

A crosslinkable functional group equivalent of the hydroxy group-containing (meth)acrylic polymer, that is, a total equivalent of the hydroxy group and the carboxy group is preferably 2,000 g/mol or less, more preferably 500 g/mol to 2,000 g/mol, and even more preferably 1,000 g/mol to 2,000 g/mol.

The crosslinkable functional group equivalent corresponds to a molecular weight between crosslinking points, and is a physical property value that governs an elastic modulus after crosslinking, that is, an elastic modulus of the reaction cured product. When the crosslinkable functional group equivalent is equal to or less than an upper limit value of the above range, the elastic modulus of the reaction cured product is increased, and the releasability of the adhesive layer from a resin, an electronic component, and the like is excellent. Further, migration of the component of the adhesive layer to a resin, an electronic component, or the like can be prevented.

In the hydroxy group-containing (meth)acrylic polymer, the hydroxy group may be present in a side group, may be present at a main chain end, or may be present in both a side chain and a main chain. From the viewpoint of easily adjusting the content of the hydroxy group, the hydroxyl group is preferably present in at least a side group.

The hydroxy group-containing (meth)acrylic polymer whose hydroxy group is present in a side group is preferably a copolymer having the following unit (c1) and unit (c2).
Unit (c1): a hydroxy group-containing (meth)acrylate unit
Unit (c2): a unit other than the unit (cl)

Examples of the unit (c1) include the following units.
—(CH₂—CR¹(COO—R²—OH))—

In the unit (c1), R¹ is a hydrogen atom or a methyl group, and R² is an alkylene group having 2 to 10 carbon atoms, a cycloalkylene group having 3 to 10 carbon atoms, or —R³—OCO—R⁵—COO—R⁴—. R³ and R⁴ each independently represent an alkylene group having 2 to 10 carbon atoms, and R⁵ is a phenylene group.
R¹ is preferably a hydrogen atom.
The alkylene group represented by R², R³, and R⁴ may be linear or branched.

Specific example of the monomer serving as the unit (c1) include 2-hydroxyethyl (meth)acrylate, 2-hydroxypropyl (meth)acrylate, 4-hydroxybutyl (meth)acrylate, 1,4-cyclohexanedimethanol monoacrylate, and 2-acryloyloxyethyl-2-hydroxyethyl-phthalic acid. The monomer serving as the unit (c1) may be used alone or in combination of two or more kinds thereof.

From the viewpoint of excellent reactivity of the hydroxy group, the unit (c1) is preferably a unit whose R² is an alkylene group having 2 to 10 carbon atoms. That is, a hydroxyalkyl (meth)acrylate unit having a hydroxy alkyl group having 2 to 10 carbon atoms is preferred.

A proportion of the unit (c1) to a total (100 mol %) of all the units constituting the hydroxy group-containing (meth)acrylic polymer is preferably 3 mol % to 30 mol %, and more preferably 3 mol % to 20 mol %. When the proportion of the unit (c1) is equal to or more than a lower limit value of the above range, the crosslinking density due to the polyfunctional isocyanate compound is sufficiently high, and the releasability of the adhesive layer from a resin, an electronic component, and the like is excellent. When the proportion of the unit (c1) is equal to or less than an upper limit value of the above range, the adhesion of the adhesive layer is excellent.

The unit (c2) is not particularly limited as long as it can be copolymerized with the monomer forming the unit (c1). The unit (c2) may have a carboxy group, and preferably does not have a reactive group (for example, an amino group) capable of reacting with an isocyanate group other than the carboxy group.

Examples of the monomer serving as the unit (c2) include a (meth)acrylate not containing a hydroxy group, (meth)acrylic acid, acrylonitrile, and a macromer having an unsaturated double bond. Examples of the macromer having an unsaturated double bond include a macromer having a polyoxyalkylene chain such as a (meth)acrylate of a polyethylene glycol monoalkyl ether.

Examples of the (meth)acrylate not containing a hydroxy group include an alkyl (meth)acrylate, cyclohexyl (meth)acrylate, phenyl (meth)acrylate, toluyl (meth)acrylate, benzyl (meth)acrylate, 2-methoxyethyl (meth)acrylate, 3-methoxybutyl (meth)acrylate, glycidyl (meth)acrylate, 2-aminoethyl (meth)acrylate, 3-(methacryloyloxypropyl)trimethoxysilane, trifluoromethylmethyl (meth)acrylate, 2-trifluoromethylethyl (meth)acrylate, 2-perfluoroethylethyl (meth)acrylate, 2-perfluoroethyl-2-perfluorobutylethyl (meth)acrylate, 2-perfluoroethyl (meth)acrylate, perfluoromethyl (meth)acrylate, diperfluoromethylmethyl (meth)acrylate, 2-perfluoromethyl-2-perfluoroethylmethyl (meth)acrylate, 2-perfluorohexylethyl (meth)acrylate, 2-perfluorodecylethyl (meth)acrylate, and 2-perfluorohexadecylethyl (meth)acrylate.

The alkyl (meth)acrylate is preferably a compound whose alkyl group has 1 to 12 carbon atoms. Examples thereof include methyl (meth)acrylate, ethyl (meth)acrylate, butyl (meth)acrylate, 2-ethylhexyl (meth)acrylate, n-propyl (meth)acrylate, isopropyl (meth)acrylate, isobutyl (meth)acrylate, t-butyl (meth)acrylate, n-pentyl (meth)acrylate, n-hexyl (meth)acrylate, n-heptyl (meth)acrylate, n-octyl (meth)acrylate, nonyl (meth)acrylate, decyl (meth)acrylate, and dodecyl (meth)acrylate.

The unit (c2) preferably includes at least an alkyl (meth)acrylate unit.

A proportion of the alkyl (meth)acrylate unit to the total (100 mol %) of all the units constituting the hydroxy group-containing (meth)acrylic polymer is preferably 60 mol % to 97 mol %, more preferably 70 mol % to 97 mol %, and even more preferably 80 mol % to 97 mol %. When the proportion of the alkyl (meth)acrylate unit is equal to or more than a lower limit value of the above range, a glass transition point, mechanical properties, and the like derived from the structure of the alkyl (meth)acrylate are exhibited, and the mechanical strength and the adhesiveness of the adhesive layer are excellent. When the proportion of the alkyl acrylate unit is equal to or less than an upper limit value of the above range, the content of the hydroxy group is sufficient, so that the crosslinking density is increased and a high elastic modulus can be exhibited.

An Mw of the hydroxy group-containing (meth)acrylic polymer is preferably 100,000 to 1,200,000, more preferably 200,000 to 1,000,000, and even more preferably 200,000 to 700,000. When the Mw is equal to or more than a lower limit value of the above range, the releasability of the adhesive layer from a resin, an electronic component, and the like is excellent. When the Mw is equal to or less than an upper limit value of the above range, the adhesion of the adhesive layer is excellent.

The Mw of the hydroxy group-containing (meth)acrylic polymer is a value in terms of polystyrene, which is obtained by measurement by gel permeation chromatography using a calibration curve prepared using a standard polystyrene sample having a known molecular weight.

A glass transition temperature (Tg) of the hydroxy group-containing (meth)acrylic polymer is preferably 20° C. or lower, and more preferably 0° C. or lower. When the Tg is equal to or more than a lower limit value of the above range, the adhesive layer exhibits sufficient flexibility even at low temperatures and is hardly peeled off from the substrate.

The lower limit value of the Tg is not particularly limited, and the Tg is preferably −60° C. or higher in the above-described molecular weight range.

The Tg means a midpoint glass transition temperature measured by differential scanning calorimetry (DSC).

(Polyfunctional Isocyanate Compound)

The polyfunctional isocyanate compound is a compound having 2 or more isocyanate groups, and is preferably a compound having 3 to 10 isocyanate groups.

Examples of the polyfunctional isocyanate compound include hexamethylene diisocyanate (HDI), tolylene diisocyanate (TDI), diphenylmethane diisocyanate (MDI), naphthalene diisocyanate (NDI), tolidine diisocyanate (TODI), isophorone diisocyanate (IPDI), xylylene diisocyanate (XDI), triphenylmethane triisocyanate, and tris(isocyanatophenyl)thiophosphate. Examples thereof include isocyanurates (trimers) and biurets of the polyfunctional isocyanate compounds, and adducts of the polyfunctional isocyanate compounds and polyol compounds.

The polyfunctional isocyanate compound preferably has an isocyanurate ring from the viewpoint that the reaction cured product (the adhesive layer) exhibits a high elastic modulus due to flatness of the ring structure.

Examples of the polyfunctional isocyanate compound having an isocyanurate ring include an isocyanurate of HDI (isocyanurate type HDI), an isocyanurate of TDI (isocyanurate type TDI), and an isocyanurate of MDI (isocyanurate type MDI).

### (Other Components)

Examples of other components used in the adhesive layer include a crosslinking catalyst (amines, a metal compound, an acid, etc.), a reinforcing filler, a coloring dye, a pigment, and an antistatic agent.

When a polyfunctional isocyanate compound is used as a crosslinking agent, the crosslinking catalyst may be any substance that functions as a catalyst for a reaction (a urethanization reaction) between the hydroxy group-containing acrylic copolymer and the crosslinking agent, and a general urethanization reaction catalyst can be used. Examples of the crosslinking catalyst include an amine compound such as a tertiary amine, and an organometallic compound such as an organic tin compound, an organic lead compound, and an organic zinc compound. Examples of the tertiary amine include a trialkylamine, a N,N,N′,N′-tetraalkyldiamine, a N,N-dialkylamino alcohol, triethylenediamine, a morpholine derivative, and a piperazine derivative. Examples of the organic tin compound include a dialkyltin oxide, a dialkyltin fatty acid salt, and a stannous fatty acid salt.

The crosslinking catalyst is preferably an organic tin compound, and more preferably dioctyltin oxide, dioctyltin dilaurate, dibutyltin laurate, or dibutyltin dilaurate. A dialkylacetylacetonetin complex catalyst, which is synthesized by reacting a dialkyltin ester and acetylacetone in a solvent and has a structure in which two molecules of acetylacetone are coordinated to one atom of dialkyltin, can be used.

An amount of the crosslinking catalyst to be used is preferably 0.01 parts by mass to 0.5 parts by mass with respect to 100 parts by mass of the hydroxy group-containing (meth)acrylic polymer.

Examples of the antistatic agent include an ionic liquid, a conductive polymer, a metal ion-conducting salt, and a conductive metal oxide.

The conductive polymer is a polymer in which electrons move and diffuse along a skeleton of the polymer. Examples of the conductive polymer include a polyaniline polymer, a polyacetylene polymer, a polyparaphenylene polymer, a polypyrrole polymer, a polythiophene polymer, and a polyvinylcarbazole polymer.

Examples of the metal ion-conducting salt include a lithium salt compound.

Examples of the conductive metal oxide include tin oxide, tin-doped indium oxide, antimony-doped tin oxide, phosphorus-doped tin oxide, zinc antimonate, and antimony oxide.

An amount of the antistatic agent to be used is appropriately set according to a desired surface resistance value of the adhesive layer.

A total content of the hydroxy group-containing (meth)acrylic polymer and the polyfunctional isocyanate compound in an adhesive layer composition used for forming the adhesive layer is preferably 50 mass % or more, more preferably 60 mass % or more, and even more preferably 70 mass % or more, with respect to a total amount of the adhesive layer composition. The adhesive layer composition does not include a liquid medium.

### [Thickness of Adhesive Layer]

A thickness of the adhesive layer is preferably 0.05 μm to 3.0 μm, more preferably 0.05 μm to 2.5 μm, and even more preferably 0.05 μm to 2.0 μm. When the thickness of the adhesive layer is equal to or more than a lower limit value of the above range, the releasability is excellent. When the thickness of the adhesive layer is equal to or less than an upper limit value of the above range, the coating stability is excellent. When the thickness of the adhesive layer is equal to or less than an upper limit value of the above range, a tack after coating does not become too strong, and a continuous coating process becomes easy.

### <Other Layers>

The film may or may not include a layer other than the substrate, the base layer, and the adhesive layer. Examples of the other layers include a gas barrier layer, an antistatic layer, and a coloring layer. The layers may be used alone or in combination of two or more kinds thereof.

From the viewpoint of effectively preventing breakage of the semiconductor device or the like due to discharge during peeling, it is preferred to have an antistatic layer between the substrate and the base layer or between the base layer and the adhesive layer. That is, the film may include the substrate, the antistatic layer, the base layer, and the adhesive layer in this order, or may include the substrate, the base layer, the antistatic layer, and the adhesive layer in this order.

The antistatic layer is a layer containing an antistatic agent. Examples of the antistatic agent include those described above.

In the antistatic layer, the antistatic agent is preferably dispersed in a resin binder. The resin binder preferably has heat resistance to withstand heat (for example, 180° C.) in an encapsulating process. Examples thereof include an acrylic resin, a silicone resin, a urethane resin, a polyester resin, a polyamide resin, a vinyl acetate resin, an ethylene-vinyl acetate copolymer, an ethylene-vinyl alcohol copolymer, a chlorotrifluoroethylene-vinyl alcohol copolymer, and a tetrafluoroethylene-vinyl alcohol copolymer.

The resin binder may be crosslinked. When the resin binder is crosslinked, the heat resistance is excellent as compared with a case where the resin binder is not crosslinked.

A thickness of the antistatic layer is preferably 0.05 μm to 3.0 μm, and more preferably from 0.1 μm to 2.5 μm. When the thickness of the antistatic layer is equal to or more than a lower limit value of the above range, conductivity is exhibited and an antistatic function is excellent. When the thickness of the antistatic layer is equal to or less than an upper limit value of the above range, production process stability including appearance stability of a coated surface is excellent.

A surface resistance value of the antistatic layer is preferably 10¹⁰ Ω/□ or less, and more preferably 10⁹ Ω/□ or less.

### [Film Manufacturing Method]

The film is manufactured, for example, by the following method.

A base layer coating liquid containing a liquid medium and a base layer composition containing a (meth)acrylic polymer and a curing agent is applied to one surface of a substrate and dried to form a base layer. An adhesive layer coating liquid containing an adhesive layer composition and a liquid medium is applied to a surface of the formed base layer on a side opposite to the substrate and dried to form an adhesive layer. After the base layer is formed, an antistatic layer may be formed, and then an adhesive layer may be formed. Any other layer may be formed. In the formation of each layer, heating may be performed to promote curing.

### [Characteristics of Film]

### (Surface Resistance Value)

A surface resistance value of the film is not particularly limited, and may be 10¹⁷ Ω/□ or less, preferably 10¹¹ Ω/□ or less, more preferably 10¹⁰ Ω/□ or less, and even more preferably 10⁹ Ω/□ or less. A lower limit of the surface resistance value is not particularly limited.

The surface resistance value of the film is measured according to IEC 60093:1980: double ring electrode method at an applied voltage of 500 V for an application time of 1 minute. As a measurement device, for example, an ultra-high resistance meter R8340 (Advantec) can be used.

### [Use of Film]

The film of the present disclosure is useful as, for example, a mold release film used in a process of encapsulating a semiconductor device with a curable resin. Among them, it is particularly useful as a mold release film used in a process of producing a semiconductor package having a complicated shape, for example, an encapsulated body in which a part of an electronic component is exposed from the resin.

### <<Method for Manufacturing Semiconductor Package>>

In one aspect, a method for manufacturing a semiconductor package includes:
placing the film according to the present disclosure in an inner surface of a mold;
placing a substrate to which a semiconductor device is fixed in the mold in which the film is placed;
encapsulating the semiconductor device in the mold with a curable resin to prepare an encapsulated body; and
releasing the encapsulated body from the mold.

Examples of the semiconductor package include: an integrated circuit in which semiconductor devices such as a transistor and a diode are integrated; and a light-emitting diode including a light-emitting device.

A package shape of the integrated circuit may cover the entire integrated circuit, or may cover a part of the integrated circuit, that is, may expose a part of the integrated circuit. Specific examples include a ball grid array (BGA), a quad flat non-leaded package (QFN), and a small outline non-leaded package (SON).

From the viewpoint of productivity, the semiconductor package is preferably manufactured through collective encapsulating and singulation, and examples thereof include an integrated circuit whose encapsulating method is a moldied array packaging (MAP) method or a wafer lebel packaging (WL) method.

The curable resin is preferably a thermosetting resin such as an epoxy resin or a silicone resin, and more preferably an epoxy resin.

In one aspect, the semiconductor package may or may not include an electronic component such as a source electrode or seal glass in addition to the semiconductor device. A part of the semiconductor device and the electronic component such as a source electrode and seal glass may be exposed from the resin.

As a method for manufacturing the semiconductor package, a known manufacturing method can be adopted except that the film of the present disclosure is used. For example, a transfer molding method may be used as the method for encapsulating the semiconductor device, and a known transfer molding device may be used as a device used in this method. The manufacturing conditions can also be the same as those in the known method for manufacturing a semiconductor package.

### EXAMPLE

Next, embodiments of the present disclosure will be specifically described with reference to Examples, but the embodiments of the present disclosure are not limited to these Examples.

In the following Examples, Examples 1 to 9 and 13 to 17 are Examples, and Examples 10 to 12 are Comparative Examples.

Materials used for forming each layer are as follows.

### <Substrate>

ETFE film 1: Fluon (registered trademark) ETFE C-88AXP (manufactured by AGC Inc.) was fed to an extruder equipped with a T-die, and taken up between a pressing roller with an uneven surface and a metal roller with a mirror surface to form a film having a thickness of 50 μm. A temperature of the extruder and the T-die was 320° C., and a temperature of the pressing roller and the metal roller was 100° C. Ra of a surface of the obtained film was 2.0 μm on a pressing roller side and 0.2 μm on a mirror surface side.

ETFE film 2: The ETFE film 1 was subjected to a corona treatment on the mirror surface side. A wetting tension of the corona-treated surface was 50 mN/m based on ISO 8296:1987 (JIS K6768:1999).

ETFE film 3: Both surfaces of the ETFE film 1 were subjected to a plasma treatment at a discharge power density of 300 Wmin/m² by applying a high-frequency voltage of 110 KHz under an argon atmosphere at an atmospheric pressure of 0.2 torr. A wetting tension of the plasma-treated surface was 58 mN/m based on ISO 8296:1987 (JIS K6768:1999).

ETFE film 4: Fluon (registered trademark) ETFE C-88AXP (manufactured by AGC Inc.) was fed to an extruder equipped with a T-die, and taken up between a pressing roller with a smooth surface and a metal roller with a mirror surface to form a film having a thickness of 12 μm. A temperature of the extruder and the T-die was 320° C., and a temperature of the pressing roller and the metal roller was 100° C. Ra of a surface of the obtained film was 0.2 μm on a pressing roller side and 0.2 μm on a mirror surface side. Both surfaces of the obtained film were subjected to the corona treatment. A wetting tension of the corona-treated surface was 50 mN/m based on ISO 8296:1987 (JIS K6768:1999).

ETFE film 5: Procedures same as those for the ETFE film 4 were conducted except that the obtained film was subjected to the corona treatment on a mirror surface side and the corona treatment was not performed on a pressing roller side.

ETFE film 6: The ETFE film 6 was obtained in the same manner as the ETFE film 1 except that a thickness was 25 μm. Ra of a surface of the obtained film was 2.0 μm on a pressing roller side and 0.2 μm on a mirror surface side.

Laminate 1: The ETFE film 4 was adhered onto one surface of a 12 μm thick polyester film (Ester (registered trademark) NSCW manufactured by Toyobo Co., Ltd.) via an adhesive (Crisvon (registered trademark) NT-258 manufactured by DIC Corporation:Coronate (registered trademark) 2096 manufactured by Tosoh Corporation=16:1 (mass ratio)). Next, the mirror surface side of the ETFE film 5 was adhered onto the other surface of the polyester film via an adhesive (Crisvon (registered trademark) NT-258 manufactured by DIC Corporation:Coronate (registered trademark) 2096 manufactured by Tosoh Corporation=16:1 (mass ratio)).

Laminate 2: The ETFE film 4 was adhered onto one surface of a 25 μm thick polyester film (Tetoron GEC manufactured by Toyobo Co., Ltd.) via an adhesive (Crisvon (registered trademark) NT-258 manufactured by DIC Corporation:Coronate (registered trademark) 2096 manufactured by Tosoh Corporation=16:1 (mass ratio)). Next, the mirror surface side of the ETFE film 5 was adhered onto the other surface of the polyester film via an adhesive (Crisvon (registered trademark) NT-258 manufactured by DIC Corporation:Coronate (registered trademark) 2096 manufactured by Tosoh Corporation=16:1 (mass ratio)).

Laminate 3: The ETFE film 4 was adhered onto one surface of a 38 μm thick polyester film (Tetoron GEC manufactured by Toyobo Co., Ltd.) via an adhesive (Crisvon (registered trademark) NT-258 manufactured by DIC Corporation:Coronate (registered trademark) 2096 manufactured by Tosoh Corporation=16:1 (mass ratio)).

Laminate 4: The ETFE film 4 was adhered onto one surface of a 75 μm thick polyester film (Teijin Tetoron HS74 manufactured by DuPont Hongji Films Foshan) via an adhesive (Crisvon (registered trademark) NT-258 manufactured by DIC Corporation:Coronate (registered trademark) 2096 manufactured by Tosoh Corporation=16:1 (mass ratio)).

Laminate 5: The ETFE film 4 was adhered onto one surface of a 12 μm thick polyester film (Ester (registered trademark) NSCW manufactured by Toyobo Co., Ltd.) via an adhesive (Crisvon (registered trademark) NT-258 manufactured by DIC Corporation:Coronate (registered trademark) 2096 manufactured by Tosoh Corporation=16:1 (mass ratio)). Next, the mirror surface side of the ETFE film 6 was adhered onto the other surface of the polyester film via an adhesive (Crisvon (registered trademark) NT-258 manufactured by DIC Corporation:Coronate (registered trademark) 2096 manufactured by Tosoh Corporation=16:1 (mass ratio)).

### <Base Layer Coating Liquid>

### [(Meth)acrylic Polymer]

(Meth)acrylic polymer 1: The following (meth)acrylic monomers 1 to 3 are blended and polymerized such that an acid value is 18.7 mgKOH/g and an Mw is 150,000, thereby obtaining a (meth)acrylic polymer 1.

(Meth)acrylic monomer 1: methyl methacrylate

(Meth)acrylic monomer 2: 2-ethylhexyl acrylate

(Meth)acrylic monomer 3: acrylic acid

### [Metal Chelate]

Metal chelate 1: aluminum trisacetylacetonate (trade name: aluminum chelate A manufactured by Kawaken Fine Chemicals Co., Ltd.)

### [Epoxy Compound]

Epoxy compound 1: TETRAD-X (trade name, manufactured by Mitsubishi Gas Chemical Company, Inc., N,N,N′,N′-tetraglycidyl-m-xylylenediamine, epoxy equivalent: 95 g/eq to 110 g/eq)

### <Antistatic Layer Coating Liquid>

Antistatic agent-containing material 1: Aracoat (registered trademark) AS601D (manufactured by Arakawa Chemical Industries, Ltd.), solid content: 3.4 mass %, a conductive polythiophene: 0.4 mass %, and an acrylic resin: 3.0 mass %

Curing agent 1: Aracoat (registered trademark) CL910 (manufactured by Arakawa Chemical Industries, Ltd.), solid content: 10 mass %, a polyfunctional aziridine compound

### <Adhesive Layer Coating Liquid>

(Meth)acrylic polymer 2 dilute solution: Nissetsu (registered trademark) KP2562 (manufactured by Nippon Carbide Industries Co., Inc.), solid content: 35%. The (meth)acrylic polymer 2 contains a hydroxy group and does not contain a carboxy group.

Polyfunctional isocyanate compound 1: Nissetsu CK157 (manufactured by Nippon Carbide Industries Co., Inc.), solid content: 100%, isocyanurate-type hexamethylene diisocyanate, NCO content: 21 mass %

### Example 1

[Preparation of base layer]

The (meth)acrylic polymer 1 was diluted with ethyl acetate to obtain a (meth)acrylic polymer 1 dilute solution having a solid content of 45 mass %.

The metal chelate 1 was diluted with toluene and acetylacetone to have a solid content of 7 mass %, thereby obtaining a metal chelate 1 dilute solution.

A base layer coating liquid having a solid content of 14 mass % was prepared by mixing 100 parts by mass of the (meth)acrylic polymer 1 dilute solution, 37 parts by mass of the metal chelate 1 dilute solution, and 150 parts by mass of ethyl acetate as a diluting solvent.

The base layer coating liquid was applied to the corona-treated mirror surface of the ETFE film 2 using a gravure coater and dried to form a base layer having a thickness of 0.8 μm. The coating was performed by a direct gravure method using a grid 150# roller with a width of Φ 100 mm×250 mm and a depth of 40 μm as a gravure plate. Drying was performed at 100° C. for 1 minute through a roller-support drying oven with an air volume of 19 m/sec. Next, curing was performed at 40° C. for 120 hours to obtain a base layer.

An acid value of the base layer at this time was 17.7 mgKOH/g. The acid value of the base layer was calculated by applying the following formula. Acid values in other Examples were calculated in the same manner.

Acid value (mgKOH/g) of base layer=((total mass of used carboxyl group-containing (meth)acrylic polymer)×acid value thereof)±(total solid mass of used (meth)acrylic polymer, used metal chelate, and material added additionally)

At this time, the content of the metal chelate was 5.8 parts by mass with respect to 100 parts by mass of the (meth)acrylic polymer in the base layer. The content of the metal chelate was determined using the following formula. Contents of metal chelate in other Examples were calculated in the same manner.

Content (part by mass) of metal chelate=solid content mass of metal chelate in coating liquid/(total mass of (meth)acrylic polymers 1 and 2 in coating liquid)×100

### [Preparation of Adhesive Layer]

An adhesive layer coating liquid was prepared by mixing 100 parts by mass of the (meth)acrylic polymer 2 dilute solution, 6 parts by mass of the polyfunctional isocyanate compound 1, and ethyl acetate. A blending amount of ethyl acetate was an amount such that a solid content of the adhesive layer coating liquid was 14 mass %.

The adhesive layer coating liquid was applied to the surface of the base layer using a gravure coater and dried to form an adhesive layer having a thickness of 0.8 μm. The coating was performed by a direct gravure method using a grid 150# roller with a width of Φ 100 mm×250 mm and a depth of 40 μm as a gravure plate. Drying was performed at 100° C. for 1 minute through a roller-support drying oven with an air volume of 19 m/sec. Next, curing was performed at 40° C. for 120 hours to obtain a film.

### Example 2

A film was obtained in the same manner as in Example 1 except that an antistatic layer was formed on the base layer of Example 1. The antistatic layer was formed as follows.

### [Preparation of Antistatic Layer]

An antistatic layer coating liquid having a solid content of 2 mass % was prepared by mixing 100 parts by mass of the antistatic agent-containing material 1 and 10 parts by mass of the curing agent 1. The antistatic layer coating liquid was applied to the surface of the base layer using a gravure coater and dried to form an antistatic layer having a thickness of 0.2 μm. The coating was performed by a direct gravure method using a grid 150# roller with a width of Φ 100 mm×250 mm and a depth of 40 μm as a gravure plate. Drying was performed at 100° C. for 1 minute through a roller-support drying oven with an air volume of 19 m/sec.

### Example 3

A base layer coating liquid was prepared by mixing an adhesive layer coating liquid same as that in Example 1 and a base layer coating liquid same as that in Example 1 at a mass ratio of 2:8. A film was obtained in the same manner as in Example 2 except that a base layer was prepared using this base layer coating liquid.

### Example 4

A film was obtained in the same manner as in Example 2 except that the ETFE film 3 was used instead of the ETFE film 2 as a substrate. The base layer was formed on a surface of the ETFE film 3 on a mirror surface side.

### Example 5

A base layer coating liquid was prepared by mixing an adhesive layer coating liquid same as that in Example 1 and a base layer coating liquid same as that in Example 1 at a mass ratio of 5:5. A film was obtained in the same manner as in Example 2 except that a base layer was prepared using this base layer coating liquid.

### Example 6

A film was obtained in the same manner as in Example 2 except that an epoxy compound 1 dilute solution having a solid content of 7 mass %, which is obtained by diluting the epoxy compound 1 with ethyl acetate and isopropyl alcohol, was used instead of the metal chelate 1 dilute solution as a curing agent for the base layer.

### Example 7

A film was obtained in the same manner as in Example 6 except that the ETFE film 3 was used instead of the ETFE film 2 as a substrate. The base layer was formed on a surface of the ETFE film 3 on a mirror surface side.

### Example 8

A film was obtained in the same manner as in Example 2 except that the thickness of the adhesive layer was 0.1 μm.

### Example 9

A base layer coating liquid was prepared by mixing an adhesive layer coating liquid same as that in Example 1 and a base layer coating liquid same as that in Example 1 at a mass ratio of 9:1. A film was obtained in the same manner as in Example 2 except that a base layer was prepared using this base layer coating liquid.

### Example 10

A film was obtained in the same manner as in Example 2 except that an adhesive layer coating liquid same as that in Example 1 was used as the base layer coating liquid to prepare a base layer.

### Example 11

A film was obtained in the same manner as in Example 2 except that no base layer was provided.

### Example 12

A film was obtained in the same manner as in Example 2 except that base layer and adhesive layer were not provided.

### Example 13

A film was obtained in the same manner as in Example 2 except that the laminate 1 was used instead of the ETFE film 2 as a substrate. The base layer was formed on a surface of the ETFE film 4 on a side opposite to the polyester film.

### Example 14

A film was obtained in the same manner as in Example 2 except that the laminate 2 was used instead of the ETFE film 2 as a substrate. The base layer was formed on a surface of the ETFE film 4 on a side opposite to the polyester film.

### Example 15

A film was obtained in the same manner as in Example 2 except that the laminate 3 was used instead of the ETFE film 2 as a substrate. The base layer was formed on a surface of the ETFE film 4 on a side opposite to the polyester film.

### Example 16

A film was obtained in the same manner as in Example 2 except that the laminate 4 was used instead of the ETFE film 2 as a substrate. The base layer was formed on a surface of the ETFE film 4 on a side opposite to the polyester film.

### Example 17

A film was obtained in the same manner as in Example 2 except that the laminate 5 was used instead of the ETFE film 2 as a substrate. The base layer was formed on a surface of the ETFE film 4 on a side opposite to the polyester film.

### [Evaluation]

### (Thickness)

The thicknesses (μm) of the substrate, the base layer, the antistatic layer, and the adhesive layer were measured in accordance with an ISO 4591:1992 (JIS K7130:1999) B1 method: a method for measuring a thickness of a sample taken from a plastic film or sheet by a mass method).

### [Elongation Rate of Base Layer]

The test was performed according to the following procedures 1 to 4.
1. The base layer coating liquid before curing was applied to a silicone-coated PET (an NS separator A (trade name), manufactured by Nakamoto Packs Co., Ltd.) so as to have a thickness of 100 μm after curing, and dried to prepare a PET with a base layer.
2. The obtained PET with the base layer was cut into a strip shape having a width of 20 mm, and the PET was peeled off to obtain a formed product having only the base layer.
3. The formed product having only the base layer was wound from the end to have a cylindrical shape.
4. The cylindrical formed product was tensioned using a tensile tester (RTC-131-A manufactured by Orientec Co., Ltd.) at a distance of 10 mm between grippers before applying tension and a speed of 100 mm/min, and an elongation until breakage (hereinafter, also referred to as an “elongation at break”) (mm) was measured. Measurements were made at 25° C.
Elongation rate (%)=elongation (mm) at break/distance (10 mm) between grippers before applying tension)×100

### (Surface Resistance Value)

The surface resistance value (Ω/□) of the film was measured in accordance with IEC 60093:1980: double ring electrode method. The measurement was performed using an ultra-high resistance meter R8340 (Advantec) as a measurement device at an applied voltage of 500 V for an applied time of 1 minute.

### (Peeling Degree of Adhesive Layer)

The film prepared in each Example was cut into a strip shape (width: 50 mm, length: 100 mm). The film was sandwiched and set by a gripper of a tensile tester (RTC-131-A manufactured by Orientec Co., Ltd.). The film was stretched at a distance of 25 mm between grippers before applying tension and a speed of 100 mm/min until the elongation reached 200%. A central portion of the film was cross-cut according to an adhesive cross-cut method defined in JIS-K5600-5-6:1999, then a sellotape (registered trademark) (CT-18 manufactured by Nichiban Co., Ltd.) was attached thereto, and the sellotape was pressed back and forth with a roller 20 times, and then peeled off by hand. A sample corresponding to “test result classification 0, edges of the cut are completely smooth, and there is no peeling on any grid mesh” defined in JIS-K5600-5-6:1999 was evaluated as good (A), and a sample not corresponding thereto was evaluated as poor (B).

### (Releasability)

A square aluminum foil having a thickness of 100 μm and a size of 15 cm×15 cm was placed on a square first metal plate (SUS 304) having a thickness of 3 mm and a size of 15 cm×15 cm. On the aluminum foil, a square spacer having a thickness of 100 mm and a size of 15 cm×15 cm and having a rectangular hole of 10 cm×8 cm at the center was placed, and 2 g of the following epoxy resin composition was placed near the center of the hole. Further, a square film having a size of 15 cm×15 cm was placed thereon with the surface on the adhesive layer side facing the spacer. A square second metal plate (SUS 304) having a thickness of 3 mm and a size of 15 cm×15 cm was placed thereon to prepare a laminated sample. The laminated sample was pressed at 180° C. and 10 MPa for 5 minutes to cure the epoxy resin composition. A laminate of the film, a layer of a cured epoxy resin composition, and an aluminum plate was cut to have a width of 25 mm to prepare five test pieces. A 180° peeling force at 180° C. of each test piece was measured at a speed of 100 mm/min using a tensile tester (RTC-131-A manufactured by Orientec Co., Ltd.). In a force (N)-grip movement distance curve, a peeling force average value (unit: N/cm) was determined over a grip movement distance of 25 mm to 125 mm. An arithmetic average of the peeling force average values of the five test pieces was determined, and the value was defined as the peeling force of the film against the epoxy resin at 180° C. The sample was evaluated as good (A) when the peeling force was 0.5 N/cm or less, and was evaluated as poor (B) when the peeling force was 0.5 N/cm or more.

The epoxy resin composition was obtained by pulverizing and mixing the following components with a super mixer for 5 minutes. The cured product of the epoxy resin composition had a glass transition temperature of 135° C., a storage elastic modulus of 6 GPa at 130° C., and a storage elastic modulus of 1 GPa at 180° C.
Phenylene skeleton-containing phenol aralkyl-type epoxy resin (softening point: 58° C., epoxy equivalent: 277 g/eq): 8 parts by mass
Bisphenol A-type epoxy resin (melting point: 45° C., epoxy equivalent: 172 g/eq): 2 parts by mass
Phenylene skeleton-containing phenol aralkyl resin (softening point: 65° C., hydroxyl group equivalent: 165 g/eq): 2 parts by mass
Phenol novolak resin (softening point: 80° C., hydroxyl group equivalent: 105 g/eq): 2 parts by mass
Curing accelerator (triphenylphosphine): 0.2 parts by mass
Inorganic filler (fused spherical silica with a median diameter of 16 μm): 84 parts by mass
Carnauba wax: 0.1 parts by mass
Carbon black: 0.3 parts by mass
Coupling agent (3-glycidoxypropyltrimethoxysilane): 0.2 parts by mass

### (Mold Test)

An encapsulating test was performed using an encapsulating device (a transfer molding device G-LINE Manual System, Apic Yamada Corporation). A 70 mm×230 mm copper lead frame to which a semiconductor device is fixed was used. As the encapsulating resin, an epoxy resin composition same as that used in the releasability evaluation was used.

An upper mold was provided with five protrusions each having a size of 5 mm×5 mm at equal intervals. A roll of 190 mm wide film was set in the upper mold in a roll-to-roll manner. After the lead frame to which the semiconductor device is fixed was placed on a lower mold, the film was vacuum-sucked onto the upper mold, the mold was clamped, and the curable resin was poured into the mold. At this time, in order to expose the semiconductor device from the resin, an adhesive surface of the film on the five protrusions of the upper mold was brought into direct contact with the semiconductor device to be fixed to the lower mold, and encapsulating was performed such that the encapsulating resin was filled therearound. After the pressure was applied for 5 minutes, the mold was opened and an encapsulated body was taken out. A peeling state between the film and the resin-encapsulated portion and an appearance of the exposed portion of the encapsulated body were visually observed and evaluated according to the following criteria.

### Peeling State Between Film and Resin-Encapsulated Portion

Good (A): Peeled off normally.
Poor (B): The lead frame was separated from the lower mold without being normally peeled off.

### Appearance of Exposed Portion of Semiconductor Device

Good (A): Less than 2 adhesive layers migrated from the film to the semiconductor device
Poor (A): 2 or more adhesive layers migrated from the film to the semiconductor device

Encapsulating conditions are as follows.
Mold clamping pressure: 0.5 MPa per a semiconductor device
Transfer pressure: 5 MPa
Mold temperature (encapsulating temperature): 180° C.

Evaluation results are shown in Tables 1 and 2. In Tables 1 and 2, “−” means not applicable.

TABLE 1

| Example | 1 | 2 | 3 | 4 | 5 | 6 |
|---|---|---|---|---|---|---|
| Thickness (μm) of adhesive layer | 0.8 | 0.8 | 0.8 | 0.8 | 0.8 | 0.8 |
| Thickness (μm) of antistatic layer | — | 0.2 | 0.2 | 0.2 | 0.2 | 0.2 |
| Thickness (μm) of base layer | 0.8 | 0.8 | 0.8 | 0.8 | 0.8 | 0.8 |
| Acid value (mgKOH/g) of base layer | 17.7 | 17.7 | 14.5 | 17.7 | 9.5 | 17.7 |
| Content (part by mass) of metal chelate | 5.8 | 5.8 | 4.6 | 5.8 | 3.2 | — |
| with respect to 100 parts by mass of | | | | | | |
| (meth)acrylic polymer in base layer | | | | | | |
| Content (part by mass) of epoxy compound | — | — | — | — | — | 5.8 |
| with respect to 100 parts by mass of | | | | | | |
| (meth)acrylic polymer in base layer | | | | | | |
| Surface treatment of base material | Corona | Corona | Corona | Plasma | Corona | Corona |
| Elongation rate (%) of base layer | 178 | 178 | 150 | 178 | 120 | 410 |
| Surface resistance value (Ω/□) | 5.5 × 10¹⁶ | 1.9 × 10⁹ | 2.3 × 10⁹ | 2.1 × 10⁹ | 2.3 × 10⁹ | 2.3 × 10⁹ |
| Peeling degree of adhesive layer | A | A | A | A | A | A |
| Releasability | A | A | A | A | A | A |
| Peeling state between mold release film | A | A | A | A | A | A |
| and resin-encapsulated portion | | | | | | |
| Appearance of exposed portion of | A | A | A | A | A | A |
| semiconductor device | | | | | | |
| Example | 7 | 8 | 9 | 10 | 11 | 12 |
| Thickness (μm) of adhesive layer | 0.8 | 0.1 | 0.8 | 0.8 | 0.8 | — |
| Thickness (μm) of antistatic layer | 0.2 | 0.2 | 0.2 | 0.2 | 0.2 | 0.2 |
| Thickness (μm) of base layer | 0.8 | 0.8 | 0.8 | 0.8 | — | — |
| Acid value (mgKOH/g) of base layer | 17.7 | 17.7 | 2.0 | — | — | — |
| Content (part by mass) of metal chelate | — | 5.8 | 0.7 | — | — | — |
| with respect to 100 parts by mass of | | | | | | |
| (meth)acrylic polymer in base layer | | | | | | |
| Content (part by mass) of epoxy compound | 5.8 | — | — | — | — | — |
| with respect to 100 parts by mass of | | | | | | |
| (meth)acrylic polymer in base layer | | | | | | |
| Surface treatment of base material | Plasma | Corona | Corona | Corona | Corona | Corona |
| Elongation rate (%) of base layer | 410 | 178 | 90 | 50 | — | — |
| Surface resistance value (Ω/□) | 2.3 × 10⁹ | 1.0 × 10⁷ | 2.3 × 10⁹ | 4.5 × 10⁹ | 5.5 × 10⁸ | 1.2 × 10⁸ |
| Peeling degree of adhesive layer | A | A | A | B | B | B |
| Releasability | A | A | A | A | A | A |
| Peeling state between mold release film | A | A | A | A | A | A |
| and resin-encapsulated portion | | | | | | |
| Appearance of exposed portion of | A | A | A | B | B | B |
| semiconductor device | | | | | | |

TABLE 2

| Example | 13 | 14 | 15 | 16 | 17 |
|---|---|---|---|---|---|
| Thickness (μm) of adhesive layer | 0.8 | 0.8 | 0.8 | 0.8 | 0.8 |
| Thickness (μm) of antistatic layer | 0.2 | 0.2 | 0.2 | 0.2 | 0.2 |
| Thickness (μm) of base layer | 0.8 | 0.8 | 0.8 | 0.8 | 0.8 |
| Acid value (mgKOH/g) of base layer | 17.7 | 17.7 | 17.7 | 17.7 | 17.7 |
| Content (part by mass) of metal chelate with respect to | 5.8 | 5.8 | 5.8 | 5.8 | 5.8 |
| 100 parts by mass of (meth)acrylic polymer in base | | | | | |
| layer | | | | | |
| Content (part by mass) of epoxy compound with | — | — | — | — | — |
| respect to 100 parts by mass of (meth)acrylic polymer | | | | | |
| in base layer | | | | | |
| Surface treatment of base material | Corona | Corona | Corona | Corona | Corona |
| Elongation rate (%) of base layer | 178 | 178 | 178 | 178 | 178 |
| Surface resistance value (Ω/□) | 1.9 × 10⁹ | 1.9 × 10⁹ | 1.9 × 10⁹ | 1.9 × 10⁹ | 1.9 × 10⁹ |
| Peeling degree of adhesive layer | A | A | A | A | A |
| Releasability | A | A | A | A | A |
| Peeling state between mold release film and resin- | A | A | A | A | A |
| encapsulated portion | | | | | |
| Appearance of exposed portion of semiconductor | A | A | A | A | A |
| device | | | | | |

In Tables 1 and 2, it was confirmed that since Examples 1 to 9 and 13 to 17 had the base layer of the present disclosure, migration of the component of the adhesive layer to the encapsulated body can be prevented even when the film is stretched.

### INDUSTRIAL APPLICABILITY

The film of the present disclosure is excellent in releasability when the semiconductor device is encapsulated with the curable resin, and can be less likely to cause poor appearance of the encapsulated body due to the mold release film. By using the film of the present disclosure as the mold release film, a semiconductor package such as an integrated circuit in which semiconductor devices such as a transistor and a diode and electronic components such as a source electrode and sealing glass are integrated can be manufactured.

The entire disclosure of Japanese Patent Application No. 2021-005780 is hereby incorporated by reference herein.

All literatures, patent applications, and technical standards described herein are hereby incorporated by reference to the same extent as when individual literatures, patent applications, and technical standards are specifically and individually incorporated by reference.

### REFERENCE SIGNS LIST

1. Film
2. Substrate
3. Base layer
4. Adhesive layer

1. A film comprising a substrate, a base layer, and an adhesive layer in this order, wherein the base layer comprises a reaction cured product of a (meth)acrylic polymer and a curing agent, and
the base layer has an elongation rate of 90% or more as measured by a tensile test at 25° C. and a speed of 100 mm/min and determined by the following formula,
Elongation rate (%)=(elongation (mm) at break)×100/(distance (mm) between grippers before applying tension).

2. A film comprising a substrate, a base layer, and an adhesive layer in this order,
wherein the base layer comprises a reaction cured product of a (meth)acrylic polymer and a curing agent which is at least one selected from the group consisting of a metal chelate and an epoxy compound, and
the (meth)acrylic polymer comprises a carboxy group-containing (meth)acrylic polymer.

3. The film according to claim 2, wherein the base layer has an elongation rate of 90% or more as measured by a tensile test at 25° C. and a speed of 100 mm/min and determined by the following formula,
Elongation rate (%)=(elongation (mm) at break)×100/(distance (mm) between grippers before applying tension).

4. The film according to claim 1, wherein the base layer has an acid value of 1 mgKOH/g to 80 mgKOH/g.

5. The film according to claim 1, wherein the curing agent comprises a metal chelate, and an amount of the metal chelate is 0.1 parts by mass to 10 parts by mass with respect to 100 parts by mass of the (meth)acrylic polymer.

6. The film according to claim 1, wherein the curing agent comprises an epoxy compound, and an amount of the epoxy compound is 0.1 parts by mass to 10 parts by mass with respect to 100 parts by mass of the (meth)acrylic polymer.

7. The film according to claim 1, wherein the substrate comprises a fluorine resin.

8. The film according to claim 7, wherein the fluorine resin comprises at least one selected from the group consisting of an ethylene-tetrafluoroethylene copolymer, a tetrafluoroethylene-hexafluoropropylene copolymer, a tetrafluoroethylene-perfluoro(alkyl vinyl ether) copolymer, and a tetrafluoroethylene-hexafluoropropylene-vinylidene fluoride copolymer.

9. The film according to claim 1, wherein the substrate is subjected to a corona treatment or a plasma treatment.

10. The film according to claim 1, wherein the adhesive layer comprises a reaction cured product of a hydroxy group-containing (meth)acrylic polymer and a polyfunctional isocyanate compound.

11. The film according to claim 1, further comprising an antistatic layer between the base layer and the adhesive layer.

12. The film according to claim 1, being a mold release film used in a process of encapsulating a semiconductor device with a curable resin.

13. A method for manufacturing a semiconductor package, the method comprising:
placing the film according to claim 1 in an inner surface of a mold;
placing a substrate to which a semiconductor device is fixed in the mold in which the film is placed;
encapsulating the semiconductor device in the mold with a curable resin to prepare an encapsulated body; and
releasing the encapsulated body from the mold.

14. The film according to claim 2, wherein the base layer has an acid value of 1 mgKOH/g to 80 mgKOH/g.

15. The film according to claim 2, wherein the curing agent comprises a metal chelate, and an amount of the metal chelate is 0.1 parts by mass to 10 parts by mass with respect to 100 parts by mass of the (meth)acrylic polymer.

16. The film according to claim 2, wherein the curing agent comprises an epoxy compound, and an amount of the epoxy compound is 0.1 parts by mass to 10 parts by mass with respect to 100 parts by mass of the (meth)acrylic polymer.

17. The film according to claim 2, wherein the substrate comprises a fluorine resin.

18. The film according to claim 17, wherein the fluorine resin comprises at least one selected from the group consisting of an ethylene-tetrafluoroethylene copolymer, a tetrafluoroethylene-hexafluoropropylene copolymer, a tetrafluoroethylene-perfluoro(alkyl vinyl ether) copolymer, and a tetrafluoroethylene-hexafluoropropylene-vinylidene fluoride copolymer.

19. The film according to claim 2, wherein the substrate is subjected to a corona treatment or a plasma treatment.

20. The film according to claim 2, wherein the adhesive layer comprises a reaction cured product of a hydroxy group-containing (meth)acrylic polymer and a polyfunctional isocyanate compound.

21. The film according to claim 2, further comprising an antistatic layer between the base layer and the adhesive layer.

22. The film according to claim 2, being a mold release film used in a process of encapsulating a semiconductor device with a curable resin.

23. A method for manufacturing a semiconductor package, the method comprising:
placing the film according to claim 2 in an inner surface of a mold;
placing a substrate to which a semiconductor device is fixed in the mold in which the film is placed;
encapsulating the semiconductor device in the mold with a curable resin to prepare an encapsulated body; and
releasing the encapsulated body from the mold.
